(19) United States
(12) Patent Application Publication
(10) Pub. No.: US 2011/0103156 A1
(43) Pub. Date: May 5, 2011

(54) DATA INPUT/OUTPUT CIRCUIT AND SEMICONDUCTOR MEMORY APPARATUS HAVING THE SAME

(75) Inventors: Jae Il KIM, Ichon-si (KR); Jong Chern Lee, Ichon-si (KR)

(73) Assignee: Hynix Semiconductor Inc., Ichon-si (KR)

(21) Appl. No.: 12/648,997

(22) Filed: Dec. 29, 2009

(30) Foreign Application Priority Data
Oct. 30, 2009 (KR) 10-2009-0104471

(51) Int. Cl. G11C 7/10; G11C 7/00

(52) U.S. Cl. 365/189.05; 365/191; 365/189.17

(57) ABSTRACT

A data input/output circuit includes a rank selecting section and a data input/output section. The rank selecting section is selectively connected to one of the first and second ranks in response to a chip selection signal, and outputs data to a connected rank or receives data from the connected rank. The data input/output section outputs the data transmitted from the rank selecting section through a data pad to an external device during a read operation, and outputs the data inputted to the data pad to the rank selecting section during a write operation.

### CROSS-REFERENCE TO RELATED APPLICATION

The present application claims priority under 35 U.S.C. §119(a) to Korean Application No. 10-2009-0104471, filed on Oct. 30, 2009, in the Korean Intellectual Property Office, which is incorporated herein by reference in its entirety as if set forth in full.

### BACKGROUND

1. Technical Field

Various embodiments of the present disclosure generally relate to a semiconductor memory apparatus, and more particularly, to data input/output of a semiconductor memory apparatus.

2. Related Art

A semiconductor memory apparatus inputs and outputs data by performing a write operation and a read operation. The read operation is an operation in which data stored in a memory bank is transmitted to a global input/output line and the transmitted data is outputted externally through a data pad. The write operation is an operation in which data inputted through the data pad is transmitted to the global input/output line and the data transmitted to the global input/output line is stored in a memory bank. Therefore, data input/output between an external device and the semiconductor memory apparatus is performed through the global input/output line.

FIG. 1 is a diagram illustrating a configuration of a typical semiconductor memory apparatus. Referring to FIG. 1, a semiconductor memory apparatus 1 includes two chips. The semiconductor memory apparatus 1 may perform input/output operations through a first chip and a second chip. The semiconductor memory apparatus 1 may have a storage capacity two times greater than that of a semiconductor memory apparatus composed of one chip. The semiconductor memory apparatus 1 controls the operations of the first and second chips using a chip selection command signal. The first chip is typically referred to as a first rank Rank0 and the second chip is referred to as a second rank Rank1. The semiconductor memory apparatus 1 determines, in response to the chip selection command signal, whether to perform data input/output operations through the first rank Rank0 or through the second rank Rank1.

In FIG. 1, the typical semiconductor memory apparatus 1 is composed of the first rank Rank0 which includes a first input/output driver 10, a first global input/output line GIO1, a first data input/output section 30 and a first data pad DQ0, and a second rank Rank1 which includes a second input/output driver 20, a second global input/output line GIO2, a second data input/output section 40 and a second data pad DQ1. The first and second data pads DQ1 and DQ2 are connected to each other such that the first and second ranks Rank0 and Rank1 may constitute one semiconductor memory apparatus 1. In the first rank Rank0, data stored in a memory bank of the first rank Rank0 is amplified through the first input/output driver 10 and is transmitted through the first global input/output line GIO1. The data transmitted through the first global input/output line GIO1 is outputted through the first data input/output section 30 and the first data pad DQ0. Further, data inputted from an external device is amplified by the first data input/output section 30 and is transmitted through the first global input/output line GIO1, and the data transmitted through the first global input/output line GIO1 is stored in the memory bank through the first input/output driver 10.

Similarly, in the second rank Rank1, data stored in a memory bank of the second rank Rank1 is amplified through the second input/output driver 20 and is transmitted through the second global input/output line GIO2, and the data transmitted through the second global input/output line GIO2 is outputted through the second data input/output section 40 and the second data pad DQ1. Further, data inputted from an external device is amplified by the second data input/output section 40 and is transmitted through the second global input/output line GIO2, and the data transmitted through the second global input/output GIO2 is stored in the memory bank through the second input/output driver 20.

The first and second input/output drivers 10 and 20 respectively include write drivers 11 and 21 and read sense amplifiers 12 and 22. The write drivers 11 and 21 participate in write operations, that is, data input, and the read sense amplifiers 12 and 22 participate in read operations, that is, data output.

The first and second data input/output sections 30 and 40 respectively include data buffers 31 and 41, data aligning units 32 and 42, write sense amplifiers 33 and 43, pipe latch units 34 and 44, data trigger units 35 and 45, and read drivers 36 and 46. The data buffers 31 and 41, the data aligning units 32 and 42 and the write sense amplifiers 33 and 43 participate in write operations, and the pipe latches 34 and 44, the data trigger units 35 and 45 and the read drivers 36 and 46 participate in read operations. In the first Rank0, data inputted through the data pad DQ0 is amplified by the data buffer 31, the amplified data is aligned by the data aligning unit 32, the aligned data is amplified by the write sense amplifier 33, and the amplified data is transmitted to the first global input/output line GIO1. The pipe latch 34 stores data transmitted through the first global input/output line GIO1, and the data trigger unit 35 outputs the stored data in synchronization with a clock signal. The outputted data is amplified by the read driver 36 and the amplified data is transmitted to the data pad DQ0. The second data input/output section 40 of the second rank Rank1 may operate in the same manner as the first rank Rank0.

As described above, since the data pads DQ0 and DQ1 of the first and second ranks Rank0 and Rank1 are connected to each other, the first and second ranks Rank0 and Rank1 may operate while constituting one semiconductor memory apparatus. However, although the first and second ranks Rank0 and Rank1 constitute one semiconductor memory apparatus, input/output circuits cannot be separately provided for the respective first and second ranks Rank0 and Rank1.

### SUMMARY OF THE INVENTION

Various aspects of the present invention comprise a semiconductor memory apparatus capable of sharing a data input/output circuit.

In one aspect of the present invention, a data input/output circuit comprises a rank selecting section configured to be selectively connected to one of a first and second ranks in response to a chip selection signal, and output data to a connected rank or receive data from the connected rank; and a data input/output section configured to output the data transmitted from the rank selecting section through a data pad to an device during a read operation, and output the data inputted to the data pad to the rank selecting section during a write operation.

In another aspect of the present invention, a semiconductor memory apparatus comprises a first data input/output line connected to a first rank; a second data input/output line connected to a second rank; and a shared data input/output section configured to output data, transmitted from one of the first and second data input/output lines through a data pad in response to a chip selection signal during a read operation, and transmit data inputted through the data pad to one of the first and second data input/output lines in response to the chip selection signal during a write operation.

In still another aspect of the present invention, a semiconductor memory apparatus comprises a first data input/output line connected to a first rank; a second data input/output line connected to a second rank; a read selecting part configured to be activated during a read operation and be connected to one of the first and second data input/output lines in response to a chip selection signal; a data output part configured to output data outputted from the read selecting part through a data pad; a write selecting part configured to be activated during a write operation and be connected to one of the first and second data input/output lines in response to the chip selection signal; and a data input part configured to output data inputted through the data pad to the write selecting part.

In still another aspect of the present invention, a semiconductor memory apparatus comprising a main chip and a plurality of slave chips comprises a rank selecting section configured to be placed in the main chip and be selectively connected to the plurality of slave chips in response to a chip selection signal; and a data input/output section configured to be placed in the main chip, output data transmitted from the rank selecting section to a data pad during a read operation, and output data inputted through the data pad to the rank selecting section during a write operation.

In still another aspect of the present invention, a semiconductor memory apparatus including a main chip and a plurality of slave chips comprises a plurality of data input/output lines respectively connected to the plurality of slave chips; and a shared data input/output section configured to be placed in the main chip, output data transmitted from one of the plurality of data input/output lines through a data pad in response to a chip selection signal during a read operation, and output data inputted through the data pad to one of the plurality of data input/output lines in response to the chip selection signal during a write operation.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 is a diagram illustrating a configuration of a typical semiconductor memory apparatus.

FIG. 2 is a block diagram schematically illustrating the configuration of a semiconductor memory apparatus in accordance with one embodiment of the present invention.

FIG. 3 is a view illustrating the detailed configuration of the semiconductor memory apparatus shown in FIG. 2.

FIGS. 4A and 4B are timing diagrams illustrating operations of the semiconductor memory apparatus according to a typical semiconductor apparatus and the present invention.

FIG. 5 is a diagram schematically illustrating the configuration of a semiconductor memory apparatus in accordance with one embodiment of the present invention.

### DETAILED DESCRIPTION OF THE EMBODIMENTS

Advantages and characteristics of the present invention and a method for achieving them will be apparent with reference to embodiments described below with reference to the accompanying drawings. However, the present invention is not limited to the exemplary embodiments described below but may be implemented in various forms. Therefore, the exemplary embodiments are provided to enable those skilled in the art to thoroughly understand the teaching of the present invention and to completely inform the scope of the present invention and the exemplary embodiment is just defined by the scope of the appended claims. Throughout the specification, like elements refer to like reference numerals.

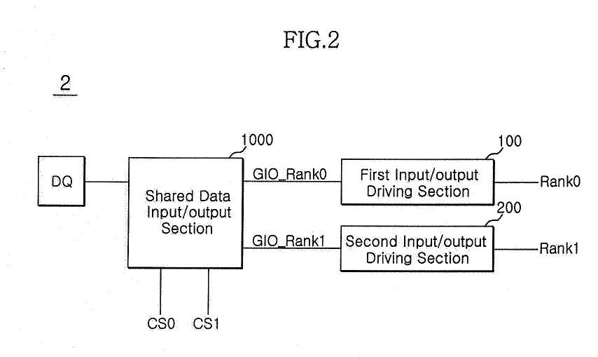

FIG. 2 is a block diagram schematically illustrating a configuration of a semiconductor memory apparatus in accordance with one embodiment of the present invention. Referring to FIG. 2, a semiconductor memory apparatus 2 includes first and second input/output driving sections 100 and 200, first and second data input/output lines GIO_Rank0 and GIO_Rank1, and a shared data input/output section 1000.

The first input/output driving section 100 stores data transmitted through the first data input/output line GIO_Rank0 in a memory bank of a first rank Rank0 during a write operation, amplifies data stored in the memory bank of the first rank Rank0 and outputs the amplified data to the first data input/output line GIO_Rank0 during a read operation. The second input/output driving section 200 stores data transmitted through the second data input/output line GIO_Rank1 in a memory bank of a second rank Rank1 during a write operation and amplifies data stored in the memory bank of the second rank Rank1 and outputs the amplified data to the second data input/output line GIO_Rank1 during a read operation.

The ranks can be defined in a variety of ways. For example, one chip may operate as a plurality of ranks and a plurality of chips may operate as a plurality of ranks. In the former case, when a memory bank of one chip having storage capacity of, for example, 1 gigabyte (Gb), is divided into two memory banks, each having a storage capacity of 512 megabytes (Mb), so that one chip operates like two chips, the divided memory banks may be defined as ranks. In the latter case, when two chips operate as one semiconductor memory apparatus, the two chips may be respectively defined as ranks. it is to be understood that the present invention is not limited to the ranks according to these two definitions and may be applied to all semiconductor memory apparatuses which adopt a concept of rank.

During a read operation, the shared data input/output section 1000 outputs data transmitted from the first input/output driving sections 100 and 200 through a data pad DQ in response to chip selection signals CS0 and CS1. During a write operation, the shared data input/output section 1000 transmits data inputted through the data pad DQ to one of the first and second input/output driving sections 100 and 200 in response to the chip selection signals CS0 and CS1. The first and second data input/output lines GIO_Rank0 and GIO_Rank1 connect the shared data input/output section 1000 to the respective first and second input/output driving sections 100 and 200. In other words, data transmission between the shared data input/output section 1000 and the first and second input/output driving sections 100 and 200 may be implemented through the first and second data input/output lines GIO_Rank0 and GIO_Rank1.

During the read operation, when the first rank Rank0 is selected by the chip selection signals CS0 and CS1, that is, when a first chip selection signal CS0 is enabled, the shared data input/output section 1000 outputs data, transmitted through the first data input/output line GIO_Rank0, to the data pad DQ. Therefore, the read operation of the first rank Rank0 may be performed. Also, during the read operation, when the second rank Rank1 is selected by the chip selection signals CS0 and CS1, that is, when a second chip selection signal CS1 is enabled, the shared data input/output section 1000 outputs data transmitted through the second data input/output line GIO_Rank1 to the data pad DQ. Therefore, the read operation of the second rank Rank1 may be performed.

During the write operation, when the first chip selection signal CS0 is enabled, the shared data input/output section 1000 outputs data, inputted through the data pad DQ, to the first data input/output line GIO_Rank0. Therefore, the write operation of the first rank Rank0 may be performed. Also, during the write operation, when the second chip selection signal CS1 is enabled, the shared data input/output section 1000 outputs data, inputted through the data pad DQ, to the second data input/output line GIO_Rank1. Therefore, the write operation of the second rank Rank1 may be performed.

Accordingly, even though the first and second ranks Rank0 and Rank1 may comprise one data input/output circuit, the semiconductor memory apparatus 2 may allow a read operation and a write operation to be selectively performed for one of the first and second ranks Rank0 and Rank1 in response to the chip selection signals CS0 and CS1, whereby it is possible to prevent a data collision from occurring.

The chip selection signals CS0 and CS1 are signals that may be generated as command signals applied from a device external to the semiconductor memory apparatus 2 and buffered. In general, if command signals are applied from an external device, the command signals are buffered by a buffer which is provided in the semiconductor memory apparatus and may be utilized as internal signals. Thus, the chip selection signals CS0 and CS1 may be understood as signals obtained because the chip selection command signals are buffered.

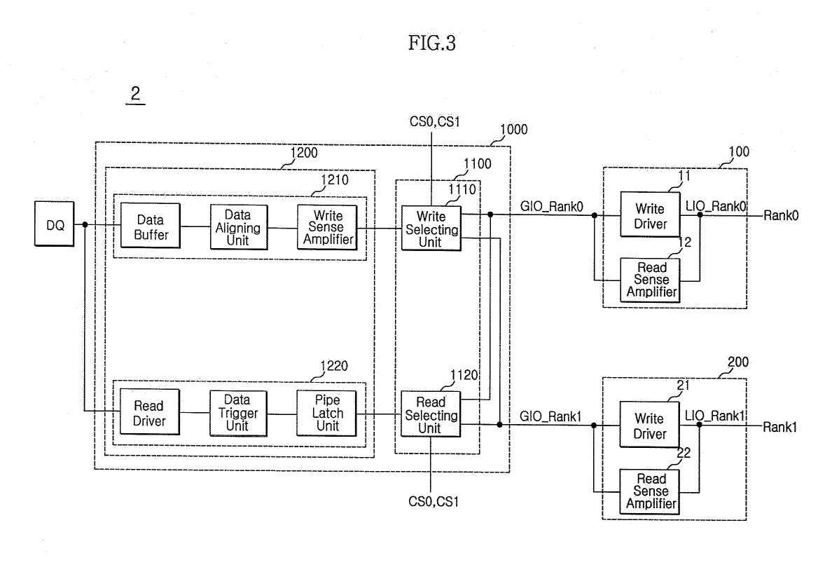

FIG. 3 is a diagram illustrating a detailed configuration of the semiconductor memory apparatus 2 shown in FIG. 2. In FIG. 3, the first and second data input/output driving sections 100 and 200 respectively include write drivers 11 and 21 and read sense amplifiers 12 and 22. During read operations, the read sense amplifiers 12 and 22 amplify data stored in the first and second ranks Rank0 and Rank1 and output the amplified data to the first and second data input/output lines GIO_Rank0 and GIO_Rank1. During write operations, the write drivers 11 and 21 amplify data transmitted through the first and second data input/output lines GIO_Rank0 and GIO_Rank1 and output the amplified data to the first and second ranks Rank0 and Rank1. More specifically, the first input/output driving section 100 is connected to a memory bank of the first rank Rank0 via a first local input/output line LIO_Rank0 and the second input/output driving section 200 is connected to a memory bank of the second rank Rank1 via a second local input/output line LIO_Rank1.

The shared data input/output section 1000 includes a rank selecting unit 1100 and a data input/output unit 1200. The rank selecting unit 1100 is connected to one of the first and second data input/output lines GIO_Rank0 and GIO_Rank1 in response to the chip selection signals CS0 and CS1. The rank selecting unit 1100 connects the first data input/output line GIO_Rank0 to the data input/output unit 1200 when the first chip selection signal CS0 is enabled, and connects the second data input/output line GIO_Rank1 with the data input/output unit 1200 when the second chip selection signal CS1 is enabled.

The rank selecting unit 1100 includes a write selecting unit 1110 and a read selecting unit 1120. The write selecting unit 1110 is activated during the write operation and is connected to one of the first and second data input/output lines GIO_Rank0 and GIO_Rank1 in response to the chip selection signals CS0 and CS1. More specifically, the write selecting unit 1110 is activated during the write operation of the semiconductor memory apparatus 2. During the write operation, the write selecting unit 1110 connects the first data input/output line GIO_Rank0 with the data input/output unit 1200 when the first chip selection signal CS0 is enabled, and connects the second data input/output line GIO_Rank1 to the data input/output unit 1200 when the second chip selection signal CS1 is enabled.

The read selecting unit 1120 is activated during the read operation and is connected to one of the first and second data input/output lines GIO_Rank0 and GIO_Rank1 in response to the chip selection signals CS0 and CS1. More specifically, the read selecting unit 1120 is activated during the read operation of the semiconductor memory apparatus 2. During the read operation, the read selecting unit 1120 connects the first data input/output line GIO_Rank0 to the data input/output unit 1200 when the first chip selection signal CS0 is enabled, and connects the second data input/output line GIO_Rank1 to the data input/output unit 1200 when the second chip selection signal CS1 is enabled.

The write selecting unit 1110 and the read selecting unit 1120 may be realized using multiplexers which are connected to one of the first and second data input/output lines GIO_Rank0 and GIO_Rank1 in response to the chip selection signals CS0 and CS1.

While not shown in a drawing, the write selecting unit 1110 and the read selecting unit 1120 may be activated in response to internal write and read signals. The internal write and read signals may be signals that are generated because write and read command signals applied from a device external to the semiconductor memory apparatus 2 are buffered.

The data input/output unit 1200 is connected to the rank selecting unit 1100, outputs an output of the rank selecting unit 1100 through the data pad DQ during the read operation, and outputs data inputted through the data pad DQ to the rank selecting unit 1100 during the write operation.

The data input/output unit 1200 may include a data input part 1210 and a data output part 1220. The data input part 1210 may be activated during the write operation of the semiconductor memory apparatus 2 and the data output part 1220 may be activated during the read operation of the semiconductor memory apparatus 2. The data input part 1210 may comprise a data buffer, a data aligning unit and a write sense amplifier. Also, the data output part 1220 may comprise a pipe latch unit, a data trigger unit and a read driver. The data input part 1210 and the data output part 1220 may be configured in any known manner.

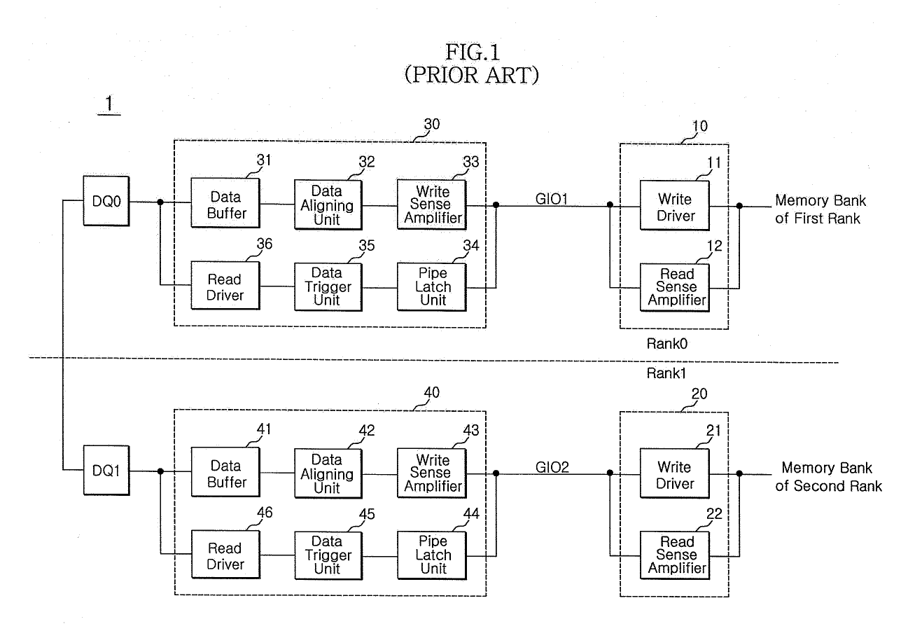

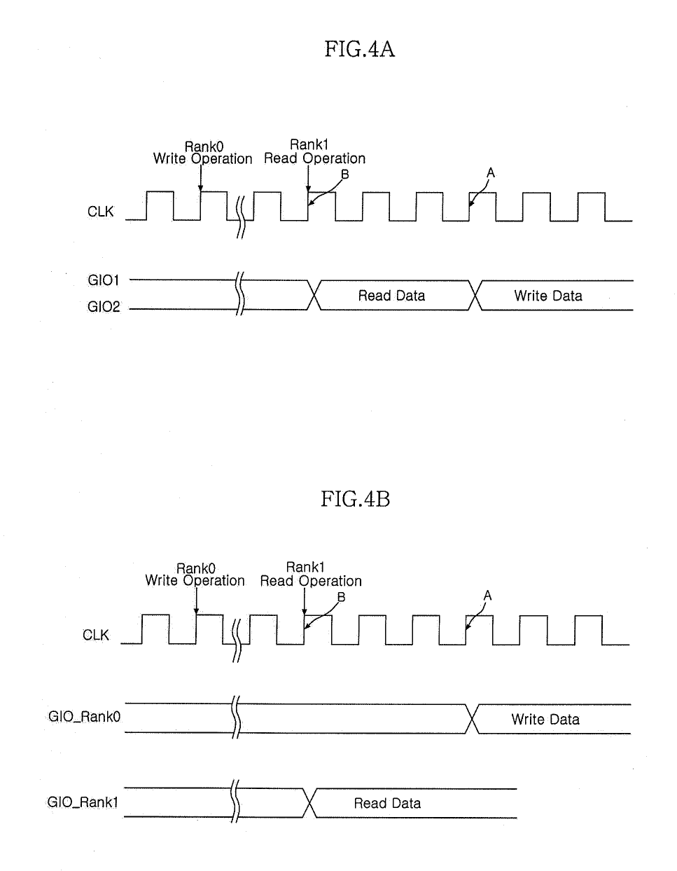

FIGS. 4A and 4B are timing diagrams illustrating operations of the semiconductor memory apparatuses according to a typical semiconductor memory apparatus and the present invention. Operations of a typical semiconductor memory apparatus and the present invention are described with reference to FIGS. 1 through 4B.

FIG. 4A shows a problem that is caused in a typical semiconductor memory apparatus because the first and second ranks Rank0 and Rank1 cannot share a data input/output circuit. Even when a read operation and a write operation for either of the first and second ranks Rank0 and Rank1 are successively performed, a data collision does not occur. That is, since the read operation and the write operation for one rank are performed with a predetermined time interval set therebetween, even when the read operation and the write operation are alternately performed, a data collision does not occur. However, in the case where the write operation of the first rank Rank0 is performed and then the read operation of the second rank Rank1 is performed, a data collision is unavoidable. Assuming that the first and second ranks Rank0 and Rank1 share a data input/output circuit, first and second data input/output lines operate in the same manner. Since it takes a time for data inputted through the data pad DQ to pass through the data input/output section, when the write operation of the first rank Rank0 is performed, a time A at which the data is actually loaded on the data input/output line is after a certain time interval is lapsed. That is to say, the write data is loaded on the data input/output line GIO1 or GIO2 at the time A.

When the read operation of the second rank Rank1 is performed following the write operation of the first rank Rank0, data of the second rank Rank1 is immediately loaded on the data input/output line GIO1 or GIO2. As a result, because the time A at which the write data is loaded on the data input/output line GIO1 and GIO2 is later than a time B at which the read data is loaded on the data input/output line GIO1 and GIO2, the data to be outputted to the data pad DQ is changed from the read data to the write data, resulting in a data collision.

Conversely, in the semiconductor memory apparatus 2 in accordance with one embodiment of the present invention, since the first and second ranks Rank0 and Rank1 share the data input/output unit 1200 and have the rank selecting unit 1100 which responds to the chip selection signals CS0 and CS1, a data collision as described above does not occur. First, when the write operation of the first rank Rank0 is performed, the first chip selection signal CS0 is enabled, and the write selecting unit 1110 of the rank selecting unit 1100 is connected to the first data input/output line GIO_Rank0. Accordingly, during the write operation, data inputted through the data pad DQ is transmitted to the write selecting unit 1110 via the data input part 1210 and the transmitted data is transmitted to the first input/output driving section 100 through the first data input/output line GIO_Rank0. The data transmitted to the first input/output driving section 100 may be stored in the memory bank of the first rank Rank0. Thereafter, when the read operation of the second rank Rank1 is performed, the second chip selection signal CS1 is enabled and the read selecting unit 1120 of the rank selecting unit 1100 is connected to the second data input/output line GIO_Rank1. Accordingly, during the read operation, data in the memory bank of the second rank Rank1, transmitted from the second input/output driving section 200, is loaded on the second data input/output line GIO_Rank1, and the data output part 1220 outputs the data, transmitted through the second data input/output line GIO_Rank1, through the data pad DQ.

The rank selecting unit 1100 distinguishes the read operation and the write operation for the first and second ranks Rank0 and Rank1 in response to the chip selection signals CS0 and CS1, and is selectively connected to the first and second data input/output lines GIO_Rank0 and GIO_Rank1. Thus, the read and write data may be transmitted through the first data input/output line GIO_Rank0 during the read and write operations of the first rank Rank0, and the read and write data may be transmitted through the second data input/output line GIO_Rank1 during the read and write operations of the second rank Rank1. Therefore, even when the read and write operations of the first and second ranks Rank0 and Rank1 are repeatedly performed, a data collision does not occur as can be alternately seen from FIG. 4B.

In order to increase the integration of a semiconductor apparatus, a three-dimensional (3D) semiconductor apparatus comprising a plurality of stacked chips has been developed. The stacked chips provide a structure that enables the 3D semiconductor apparatus to be packages in a single package. Recently, a through-silicon via (TSV) type semiconductor apparatus has been developed in which silicon vias are formed to pass through the plurality of stacked chips so that all of the chips are electrically connected to one another. In this regard, the technical concept of the semiconductor memory apparatus 2 in accordance with the embodiment of the present invention can be applied to the 3D semiconductor apparatus.

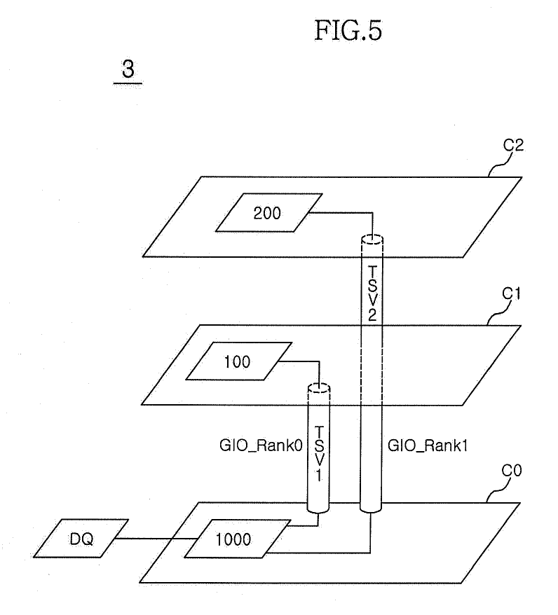

FIG. 5 is a diagram schematically illustrating a configuration of a semiconductor memory apparatus in accordance with one embodiment of the present invention. Referring to FIG. 5, a semiconductor memory apparatus 3 comprises a main chip C0 and a plurality of slave chips C1 and C2. The chips C0, C1 and C2 are connected by TSVs.

FIG. 5 shows an exemplary embodiment in which one main chip C0 and two slave chips C1 and C2 are stacked. Although only one main chip and two slave chips are shown, it is to be understood that any number of main and slave chips may be used. In the 3D semiconductor apparatus in which the plurality of chips are stacked, the plurality of chips may operate individually. Accordingly, the first and second slave chips C1 and C2 may be divided as first and second ranks Rank0 and Rank1 and be separately operated by chip selection signals CS0 and CS1. It is sufficient for a shared data input/output section 1000 to be disposed in at least one of the main chip C0 and the first and second slave chips C1 and C2. In FIG. 5, the shared data input/output section 1000 is disposed in the main chip C0.

When assuming that the first slave chip C1 is designated as the first rank Rank0 and the second slave chip C2 is designated as the second rank Rank1, the first chip selection signal CS0 becomes a signal for selecting the first slave chip C1, and the second chip selection signal CS1 becomes a signal for selecting the second slave chip C2. Data transmission between the first slave chip C1 and the main chip C0 is implemented through a first data input/output line GIO_Rank0. The first data input/output line GIO_Rank0 comprises a TSV TSV1 which connects the first slave chip C1 and the main chip C0. Data transmission between the second slave chip C2 and the main chip C0 is implemented through a second data input/output line GIO_Rank1. The second data input/output line GIO_Rank1 comprises a TSV TSV2 which connects the second slave chip C2 and the main chip C0.

It is to be understood that the shared data input/output section 1000 according to the embodiment of the present invention can be applied to a semiconductor memory apparatus in which a plurality of chips are stacked. While the semiconductor memory apparatuses having two ranks are explained with reference to FIGS. 2 and 5, a person having ordinary skill in the art will appreciate that the technical concept of the present invention can be applied to a semiconductor memory apparatus which are divided into three or more ranks.

While certain embodiments have been described above, it will be understood to those skilled in the art that the embodiments described are by way of example only. Accordingly, the data input/output circuit and the semiconductor memory apparatus having the same described herein should not be limited based on the described embodiments. Rather, the data input/output circuit and a semiconductor memory apparatus having the same described herein should only be limited in light of the claims that follow when taken in conjunction with the above description and accompanying drawings.

What is claimed is:

1. A data input/output circuit comprising:
a rank selecting section configured to be selectively connected to one of a first and second rank in response to a chip selection signal, and output data to a connected rank or receive data from the connected rank; and
a data input/output section configured to output the data transmitted from the rank selecting section through a data pad to an external device during a read operation, and output the data inputted to the data pad to the rank selecting section during a write operation.

2. The data input/output circuit according to claim 1, wherein the rank selecting section outputs the data transmitted from the first rank when the chip selection signal selects the first rank, and outputs data transmitted from the second rank when the chip selection signal selects the second rank.

3. The data input/output circuit according to claim 1, wherein the rank selecting section transmits an output of the data input/output section to the first rank when the chip selection signal selects the first rank, and transmits the output of the data input/output section to the second rank when the chip selection signal selects the second rank.

4. The data input/output circuit according to claim 1, wherein the first rank is connected to the rank selecting section through a first data input/output line, and the second rank is connected to the rank selecting section through a second data input/output line.

5. The data input/output circuit according to claim 1, wherein the chip selection signal comprises a signal that is generated by buffering a command signal inputted from the external device.

6. A semiconductor memory apparatus comprising:
a first data input/output line connected to a first rank;
a second data input/output line connected to a second rank; and
a shared data input/output section configured to output data transmitted from one of the first and second data input/output lines through a data pad in response to a chip selection signal during a read operation, and transmit data inputted through the data pad to one of the first and second data input/output lines in response to the chip selection signal during a write operation.

7. The semiconductor memory apparatus according to claim 6, wherein the shared data input/output section comprises:
a rank selecting unit configured to select one of the first and second data input/output lines in response to the chip selection signal; and
a data input/output unit configured to receive an output of the rank selecting unit and output a received output through the data pad during the read operation, and output the data inputted through the data pad to the rank selecting unit during the write operation.

8. The semiconductor memory apparatus according to claim 7, wherein the rank selecting unit outputs data transmitted from the first data input/output line when the chip selection signal selects the first rank, and outputs data transmitted from the second data input/output line when the chip selection signal selects the second rank.

9. The semiconductor memory apparatus according to claim 7, wherein the rank selecting unit transmits an output of the data input/output unit to the first data input/output line when the chip selection signal selects the first rank, and transmits an output of the data input/output unit to the second data input/output line when the chip selection signal selects the second rank.

10. The semiconductor memory apparatus according to claim 6, wherein the chip selection signal comprises a signal that is generated by buffering a command signal inputted from an external device.

11. A semiconductor memory apparatus comprising:
a first data input/output line connected to a first rank;
a second data input/output line connected to a second rank;
a read selecting part configured to be activated during a read operation and be connected to one of the first and second data input/output lines in response to a chip selection signal;
a data output part configured to output data outputted from the read selecting part through a data pad;
a write selecting part configured to be activated during a write operation and be connected to one of the first and second data input/output lines in response to the chip selection signal; and
a data input part configured to output data inputted through the data pad to the write selecting part.

12. The semiconductor memory apparatus according to claim 11, wherein the read selecting part is connected to the first data input/output line when the chip selection signal selects the first rank, and is connected to the second data input/output line when the chip selection signal selects the second rank.

13. The semiconductor memory apparatus according to claim 11, wherein the write selecting part is connected to the first data input/output line when the chip selection signal selects the first rank, and is connected to the second data input/output line when the chip selection signal selects the second rank.

14. The semiconductor memory apparatus according to claim 11, wherein the chip selection signal comprises a signal that is generated by buffering a command signal inputted from an external device.

15. A semiconductor memory apparatus comprising a main chip and a plurality of slave chips, comprising:
a rank selecting section configured to be placed in the main chip and be selectively connected to the plurality of slave chips in response to a chip selection signal; and
a data input/output section configured to be placed in the main chip, output data transmitted from the rank selecting section to a data pad during a read operation, and output data inputted through the data pad to the rank selecting section during a write operation.

16. The semiconductor memory apparatus according to claim 15, wherein the rank selecting section is connected to the plurality of slave chips through data input/output lines which are respectively assigned for the plurality of slave chips.

17. The semiconductor memory apparatus according to claim 16, wherein the data input/output lines comprise through-silicon vias (TSVs).

18. The semiconductor memory apparatus according to claim 15, wherein the chip selection signal comprises a signal that is generated by buffering a command signal inputted from an external device.

19. A semiconductor memory apparatus including a main chip and a plurality of slave chips, comprising:
a plurality of data input/output lines respectively connected to the plurality of slave chips; and
a shared data input/output section configured to be placed in the main chip, output data transmitted from one of the plurality of data input/output lines through a data pad in response to a chip selection signal during a read operation, and output data inputted through the data pad to one of the plurality of data input/output lines in response to the chip selection signal during a write operation.

20. The semiconductor memory apparatus according to claim 19, wherein the plurality of data input/output lines comprise through-silicon vias (TSVs).

21. The semiconductor memory apparatus according to claim 19, wherein the chip selection signal comprises a signal that is generated by buffering a command signal inputted from an external device.

22. The semiconductor memory apparatus according to claim 19, wherein the shared data input/output section comprises:
a rank selecting unit configured to be connected to one of the plurality of data input/output lines in response to the chip selection signal; and
a data input/output unit configured to receive an output of the rank selecting unit and output a received output through the data pad during the read operation, and output the data inputted through the data pad to the rank selecting unit during the write operation.

23. The semiconductor memory apparatus according to claim 19, wherein the rank selecting unit comprises:
a read selecting part configured to be connected to one of the plurality of data input/output lines in response to the chip selection signal during the read operation; and
a write selecting part configured to be connected to one of the plurality of data input/output lines in response to the chip selection signal during the write operation.

24. The semiconductor memory apparatus according to claim 23, wherein the data input/output unit comprises:
a data output part configured to receive an output of the read selecting part and output a received output through the data pad; and
a data input part configured to output the data, inputted through the data pad, to the write selecting part.

25. The semiconductor memory apparatus according to claim 19, wherein the chip selection signal comprises a signal that is generated by buffering a command signal inputted from an external device.
